(19) United States
(12) Patent Application Publication
(10) Pub. No.: US 2026/0223440 A1
(43) Pub. Date: Jul. 30, 2026

(54) SEMICONDUCTOR DEVICE AND METHOD OF MANUFACTURING THE SAME

(71) Applicant: Kioxia Corporation, Minato-ku, Tokyo (JP)

(72) Inventor: Shoji AOTA, Yokkaichi (JP)

(21) Appl. No.: 19/323,779

(22) Filed: Sep. 9, 2025

(30) Foreign Application Priority Data
Jan. 28, 2025 (JP) 2025-012458

(51) Int. Cl. H10D 84/80; H10D 1/68

(52) U.S. Cl. CPC H10D 84/813; H10D 1/696

(57) ABSTRACT

According to one embodiment, a semiconductor device includes a capacitance element and a transistor. The capacitance element includes a semiconductor substrate, a diffusion layer provided on the semiconductor substrate, a lower electrode layer provided on the diffusion layer and replacing a dummy polysilicon layer, an insulating film for a thick film capacitance element provided on the lower electrode layer, and an upper electrode layer provided on the insulating film. The transistor includes an active region provided on the semiconductor substrate and separated from the diffusion layer by a separation region, a source diffusion layer and a drain diffusion layer provided on the active region, and a gate electrode layer provided above the active region and replacing the dummy polysilicon layer.

### CROSS-REFERENCE TO RELATED APPLICATION

This application is based upon and claims the benefit of priority from Japanese Patent Application No. 2025-012458, filed January 28, 2025, the entire contents of which are incorporated herein by reference.

### FIELD

Embodiments described herein relate generally to a semiconductor device and a method of manufacturing the same.

### BACKGROUND

A complementary metal oxide semiconductor (CMOS) technique that combines an HKMG technique with high-k dielectric (HK)/metal gate (MG) and a replacement metal gate (RMG) technique is used for large scale integration circuit (LSI) devices such as central processing units (CPUs), various memory devices, and application specific integrated circuits (ASICs). Meanwhile, a high breakdown voltage capacitance element is used in a memory device that requires high voltage writing.

### DESCRIPTION OF THE DRAWINGS

FIG. 1A is a plan view of a semiconductor device according to a first embodiment.

FIG. 1B is a cross-sectional view taken along line I-I in FIG. 1A.

FIG. 2 is a circuit diagram of the semiconductor device according to the first embodiment.

FIG. 3 is a cross-sectional view taken along line II-II in FIG. 1B.

FIG. 4A is a plan view of a method of manufacturing the semiconductor device according to the first embodiment.

FIG. 4B is a cross-sectional view taken along line III-III in FIG. 4A.

FIG. 5A is a plan view of a method of manufacturing the semiconductor device according to the first embodiment.

FIG. 5B is a cross-sectional view taken along line IV-IV in FIG. 5A.

FIG. 6A is a plan view of a method of manufacturing the semiconductor device according to the first embodiment.

FIG. 6B is a cross-sectional view taken along line V-V in FIG. 6A.

FIG. 7A is a plan view of a method of manufacturing the semiconductor device according to the first embodiment.

FIG. 7B is a cross-sectional view taken along line VI-VI in FIG. 7A.

FIG. 8A is a plan view of a method of manufacturing the semiconductor device according to the first embodiment.

FIG. 8B is a cross-sectional view taken along line VII-VII in FIG. 8A.

FIG. 9A is a plan view of a method of manufacturing the semiconductor device according to the first embodiment.

FIG. 9B is a cross-sectional view taken along line VIII-VIII in FIG. 9A.

FIG. 10A is a plan view of a method of manufacturing the semiconductor device according to the first embodiment.

FIG. 10B is a cross-sectional view taken along line IX-IX in FIG. 10A.

FIG. 11A is a plan view of a method of manufacturing the semiconductor device according to the first embodiment.

FIG. 11B is a cross-sectional view taken along line X-X in FIG. 11A.

FIG. 12A is a plan view of a method of manufacturing the semiconductor device according to the first embodiment.

FIG. 12B is a cross-sectional view taken along line XI-XI in FIG. 12A.

FIG. 13A is a plan view of a method of manufacturing the semiconductor device according to the first embodiment.

FIG. 13B is a cross-sectional view taken along line XII-XII in FIG. 13A.

FIG. 14 is a cross-sectional view of a semiconductor device according to a second embodiment.

FIG. 15A is a plan view of a semiconductor device according to a third embodiment.

FIG. 15B is a cross-sectional view taken along line XIII-XIII in FIG. 15A.

FIG. 16 is a circuit diagram of the semiconductor device according to the third embodiment.

FIG. 17 is a cross-sectional view taken along line XIV-XIV in FIG. 15B.

FIG. 18 is a cross-sectional view of a semiconductor device according to a fourth embodiment.

FIG. 19 is a cross-sectional view of a semiconductor device according to a fifth embodiment.

FIG. 20 is a cross-sectional view of a semiconductor device according to a sixth embodiment.

FIG. 21 is a cross-sectional view of a semiconductor device according to a seventh embodiment.

### DETAILED DESCRIPTION

When the RMG technique is applied, the polysilicon gate electrode is replaced with a metal gate material. When a high breakdown voltage capacitance element is formed on the gate electrode, there is a restriction of a vertical structure specific to the RMG process.

Embodiments provide a semiconductor device and a method of manufacturing the same, the semiconductor device having a high breakdown voltage thick film capacitance element structure in which a process difficulty is reduced and a freedom of setting a film thickness is ensured without a restriction of a vertical structure specific to an RMG process.

In general, according to one embodiment, a semiconductor device includes a capacitance element and a transistor. The capacitance element includes a semiconductor substrate, a diffusion layer provided on the semiconductor substrate, a lower electrode layer provided on the diffusion layer and replacing a dummy polysilicon layer, an insulating film for a thick film capacitance element provided on the lower electrode layer, and an upper electrode layer provided on the insulating film. The transistor includes an active region provided on the semiconductor substrate and separated from the diffusion layer by a separation region, a source diffusion layer and a drain diffusion layer provided on the active region, and a gate electrode layer provided above the active region and replacing the dummy polysilicon layer.

Hereinafter, embodiments will be described with reference to the drawings. In the following description, the same reference numerals are given to the same or similar members, and the description of members that have already been described will be omitted as appropriate. In the following description, a direction perpendicular to a semiconductor substrate extending in an XY plane is referred to as a Z direction, a direction perpendicular to the Z direction and in which a lower electrode layer 30G of a capacitance element 1 extends is referred to as an X direction, and a direction perpendicular to the Z direction and the X direction is referred to as a Y direction. In addition, the high breakdown voltage capacitance element is a capacitance element having a relatively high breakdown voltage as compared to a power supply voltage of an integrated circuit such as a central processing unit (CPU). For example, a high breakdown voltage capacitance element is used for an element connected to a transistor for high voltage writing of the non-volatile memory. In addition, an upper electrode layer 38, the lower electrode layer 30G, and a gate electrode layer 30M may also be simply referred to as an electrode layer 38, an electrode layer 30G, and an electrode layer 30M.

### Configuration of Semiconductor Device

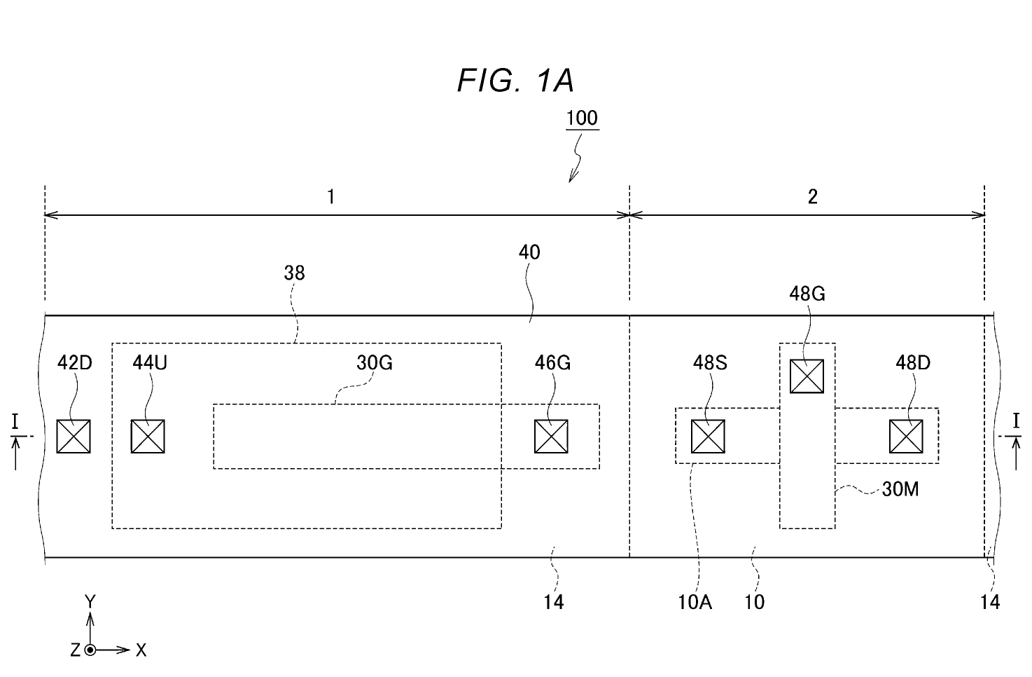

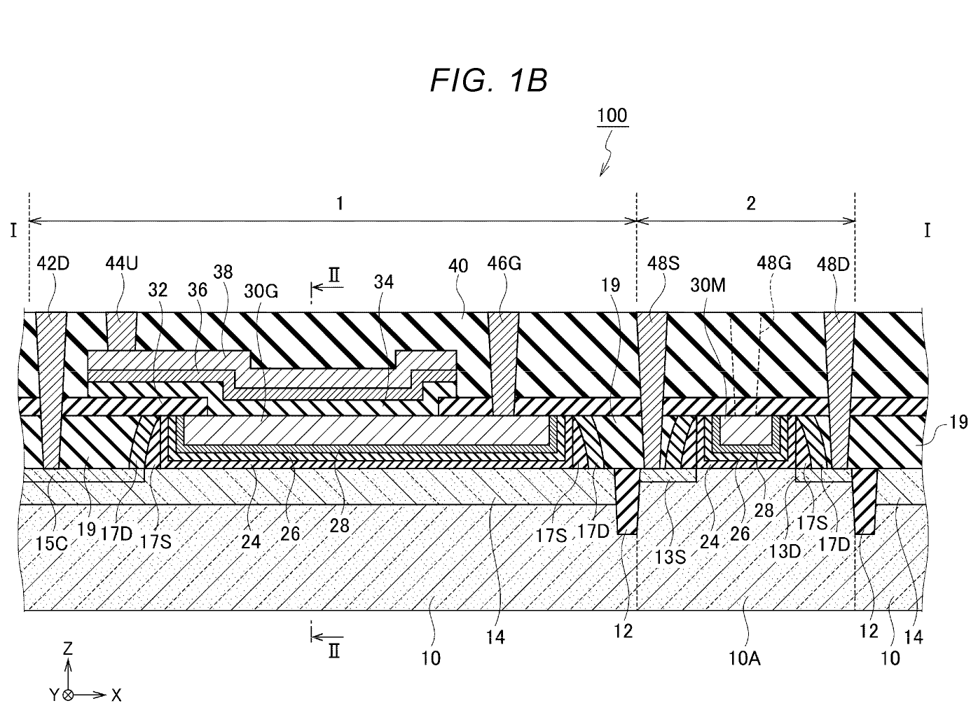

FIG. 1A is a plan view of a semiconductor device according to a first embodiment. FIG. 1B is a cross-sectional view taken along line I-I in FIG. 1A.

A semiconductor device 100 according to the first embodiment includes the capacitance element 1 and a transistor 2 provided on a semiconductor substrate 10. The semiconductor device 100 according to the first embodiment realizes a high breakdown voltage thick film capacitance element by a CMOS technique in which an HKMG technique and an RMG technique are combined.

As shown in FIGS. 1A and 1B, the capacitance element 1 includes the semiconductor substrate 10, a diffusion layer 14 provided on the semiconductor substrate 10, the lower electrode layer 30G provided on the diffusion layer 14 and replacing a dummy polysilicon layer, an insulating film 34 for a thick film capacitance element provided on the lower electrode layer 30G, and the upper electrode layer 38 provided on the insulating film 34.

The transistor 2 includes an active region 10A provided on the semiconductor substrate 10 and separated from the diffusion layer 14 by a separation region 12, a source diffusion layer 13S and a drain diffusion layer 13D provided on the active region 10A, and the gate electrode layer 30M provided on the active region 10A and replacing a dummy polysilicon layer. The separation region 12 is an insulating layer called a shallow trench isolation (STI).

In addition, as shown in FIGS. 1A and 1B, the capacitance element 1 includes a high-k dielectric layer 24 provided on the diffusion layer 14, a metal-containing layer 26 provided on the high-k dielectric layer 24, and a work function metal (WF) layer 28 provided on the metal-containing layer 26. The lower electrode layer 30G is provided on the work function metal layer 28. Although not shown in FIGS. 1A and 1B, an oxide film (interlayer: IL: SiO₂) is provided between the high-k dielectric layer 24 and the diffusion layer 14.

In addition, as shown in FIGS. 1A and 1B, the transistor 2 includes the high-k dielectric layer 24 provided on the active region 10A, the metal-containing layer 26 provided on the high-k dielectric layer 24, and the work function metal layer 28 provided on the metal-containing layer 26. The gate electrode layer 30M is provided on the work function metal layer 28. Although not shown in FIGS. 1A and 1B, the transistor 2 also has an oxide film (IL) between the high-k dielectric layer 24 and the active region 10A.

Furthermore, as shown in FIG. 1B, the semiconductor device 100 according to the first embodiment includes side wall insulating films 17S and 17D and an interlayer insulating film 19 applied to the RMG process. In addition, the device includes an insulating film 32 that covers the device surface.

In addition, the metal-containing layer 26, the work function metal layer 28, and the lower electrode layer 30G of the capacitance element 1, and the metal-containing layer 26, the work function metal layer 28, and the electrode layer 30M of the transistor 2 have the same stacked structure. Each layer can be formed at the same time by the CMOS technique in which the RMG technique and the HKMG technique are combined.

The N-channel MOSFET and the P-channel MOSFET can be applied to the transistor 2. For example, any of the N-channel MOSFET and the P-channel MOSFET can be selectively formed by appropriately selecting the ion implantation impurity and the dose amount when performing the well diffusion and the channel doping in the active region 10A, and forming the source diffusion layer 13S and the drain diffusion layer 13D. In addition, the work function metal layer 28 can be appropriately selected to control the threshold voltage of the MOSFET. In addition, the breakdown voltage of the MOSFET can be appropriately selected by controlling the thickness of the high-k dielectric layer 24 and the oxide film (IL).

In the semiconductor device 100 according to the first embodiment, a high breakdown voltage capacitance element using a thick insulating film can be realized in a gate-last process of the HKMG. The film thickness of the insulating film 34 is relatively thick in order to form the capacitance element 1 having a high breakdown voltage. For example, the film thickness of the insulating film 34 is 10 nm or more.

The height of the gate electrode in the RMG process is approximately 30 nm. In the semiconductor device 100 according to the first embodiment, the gate electrode in the RMG process is used as the lower electrode layer 30G. The insulating film 34 is disposed on the upper portion of the lower electrode layer 30G, and the upper electrode layer 38 is provided on the upper portion of the insulating film 34. Therefore, the three-layer structure of the lower electrode layer 30G/insulating film 34/upper electrode layer 38 can be easily formed. In addition, it is possible to form a capacitance element having the upper electrode layer 38 having a large area exceeding the lower electrode width limited to approximately 1 μm by the RMG process restriction.

In the semiconductor device 100 according to the first embodiment, a restriction on a gate electrode height and a gate electrode width can be avoided.

In the semiconductor device 100 according to the first embodiment, the gate electrode formed by the RMG process is used as the lower electrode, and a thick insulating film capable of ensuring a desired breakdown voltage and an upper electrode are formed on the lower electrode.

In the semiconductor device 100 according to the first embodiment, the film thickness of the upper electrode layer 38 and the lower electrode layer 30G can be increased, and the contact formation process is easy. In addition, the film thickness of the upper electrode layer 38 can also be easily controlled by a chemical mechanical polishing (CMP) technique.

In the semiconductor device 100 according to the first embodiment, it is not necessary to form the capacitance element within the restriction of the height of the gate electrode, and the freedom of setting the film thickness of the insulating film 34 and the upper electrode layer 38 can be ensured. Furthermore, the process difficulty during the electrode processing and the contact formation can also be reduced.

In addition, the electrode layers 30G and 30M are formed using a gate-last process of the HKMG process. That is, in the capacitance element 1, the electrode layer 30G is formed by forming a dummy gate, peeling the dummy gate, and embedding the gate insulating film and the electrode layer 30G in a groove having a gate shape after peeling. In the transistor 2, the gate electrode layer 30M is formed by forming the diffusion layers 13S and 13D required for the formation of the transistor using the dummy gates, peeling the dummy gates, and embedding the gate insulating film and the gate electrode layer 30M in a groove having the gate shape after peeling. Here, the gate insulating film includes an oxide film (IL) (not shown) formed on the diffusion layer 14 and the active region 10A, and the high-k dielectric layer 24 formed on the oxide film (IL). The oxide film (IL) is an insulating film represented by a silicon oxide film (SiOx). The oxide film (IL) and the high-k dielectric layer 24 may be formed before the dummy gate is formed. That is, after the oxide film (IL) and the high-k dielectric layer 24 are formed on the diffusion layer 14 and the active region 10A, the dummy gate may be formed.

The high-k dielectric layer 24 has a relative dielectric constant k of, for example, 10 or more, and may be applicable with a single layer or a multilayer selected from the group consisting of hafnium oxide (HfO₂), hafnium silicon oxide (HfSiO), lanthanum oxide (La₂O₃), tantalum oxide (Ta₂O₅), strontium titanate oxide (SrTiO₃), or zirconium oxide (ZrO₂).

The metal-containing layer 26 may be applicable with a single layer or a multilayer selected from the group consisting of titanium nitride (TiN), tantalum nitride (TaN), tantalum (Ta), or tungsten (W).

In the HKMG technique, a thin work function metal layer 28 is inserted between the high-k dielectric layer 24 and the electrode layers 30G and 30M. The threshold voltage can be adjusted by changing the thickness of the work function metal layer 28.

The work function metal layer 28 may be applied with a single layer or a multilayer selected from the group consisting of aluminum (Al), lanthanum (La), titanium (Ti), titanium nitride (TiN), and tungsten (W) as a metal film for controlling the work function value.

The electrode layers 30G and 30M may be applied with a single layer or a multilayer selected from the group consisting of tungsten (W), aluminum (Al), titanium (Ti), and titanium nitride (TiN).

As shown in FIG. 1B and FIG. 3, a metal layer 36 called a barrier metal (BM) may be provided between the insulating film 34 and the upper electrode layer 38. This is to reduce the influence on the element characteristics caused by the surface roughness of the exposed region of the insulating film 34 of the capacitance element 1. The surface roughness and the like of a surface 30S in contact with the insulating film 34 of the lower electrode layer 30G can be absorbed, and the influence on the element characteristics can be reduced. The metal layer 36 includes a single layer or a multilayer selected from the group consisting of titanium (Ti), titanium nitride (TiN), tantalum nitride (TaN), tantalum (Ta), or tungsten (W).

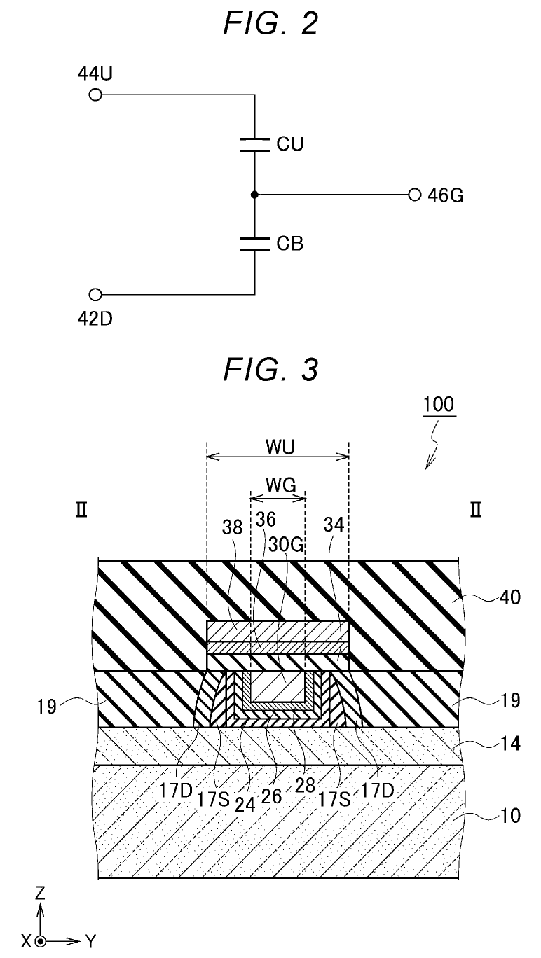

FIG. 2 is a circuit diagram of the capacitance element 1 of the semiconductor device 100 according to the first embodiment.

As shown in FIG. 2, the capacitance element 1 can be regarded as a capacitance element combining a capacitor CU formed by the upper electrode layer 38, the insulating film 34, and the lower electrode layer 30G, and a capacitor CB formed by the lower electrode layer 30G, the gate insulating film (oxide film (IL) + high-k dielectric layer 24), and the diffusion layer 14.

The capacitor CU is connected between a contact 44U connected to the upper electrode layer 38 and a contact 46G connected to the lower electrode layer 30G, and the capacitor CB is connected between a contact 42D connected to a diffusion layer 15C and the contact 46G connected to the lower electrode layer 30G.

FIG. 3 is a cross-sectional view taken along line II-II in FIG. 1B.

The film thickness of the insulating film 34 of the capacitance element 1 is relatively thick in order to form the capacitance element 1 having a high breakdown voltage. As shown in FIG. 3, the width WU of the upper electrode layer 38 in the Y direction is wider than the width WG of the lower electrode layer 30G in the Y direction.

### Method of Manufacturing Semiconductor Device according to First Embodiment

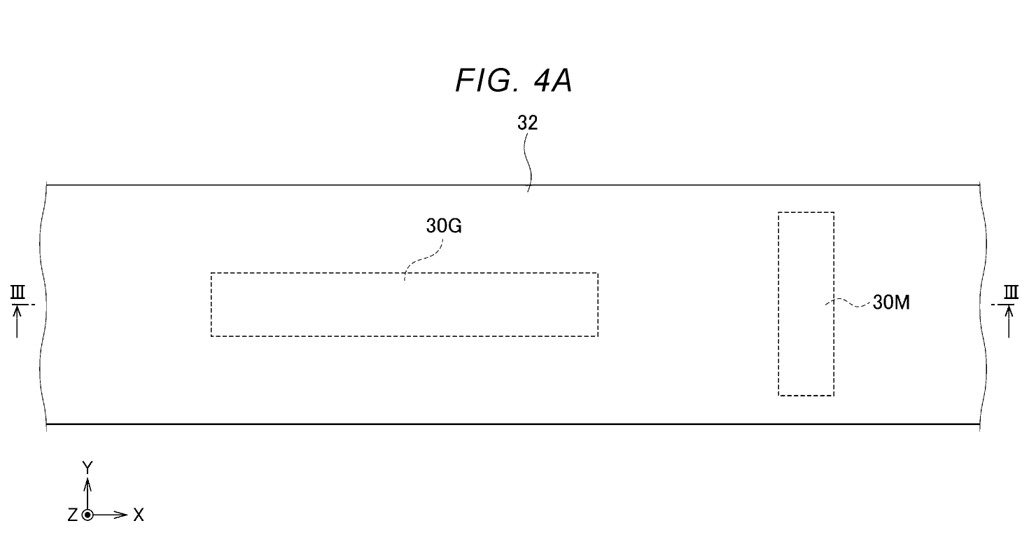

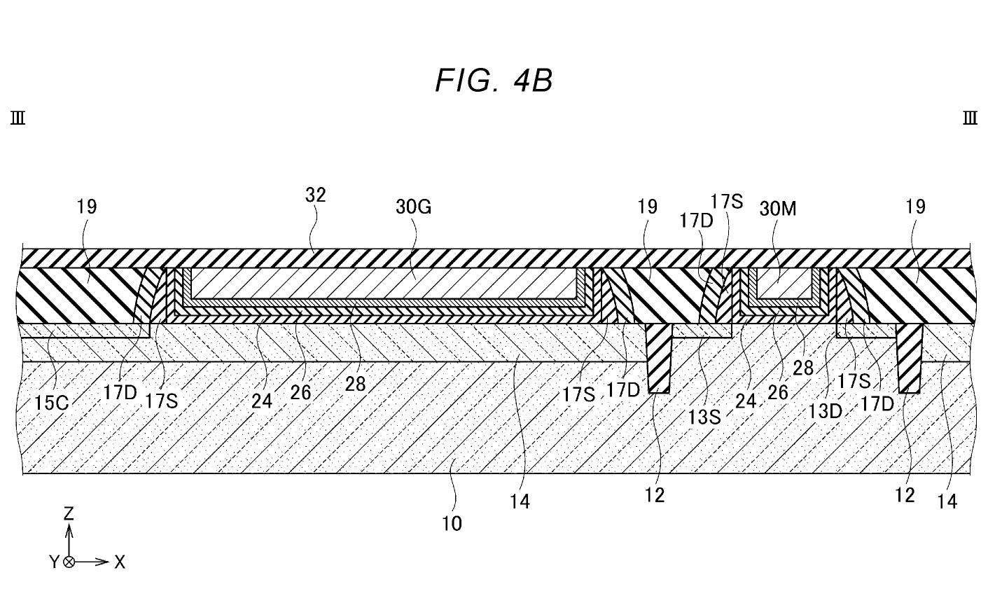

(A) FIG. 4A is a plan view of a method of manufacturing the semiconductor device according to the first embodiment, and FIG. 4B is a cross-sectional view taken along line III-III in FIG. 4A. First, as shown in FIGS. 4A and 4B, the electrode layers 30G and 30M are formed by the RMG process, and then the insulating film 32 is formed. The insulating film 32 is called a block insulating film.

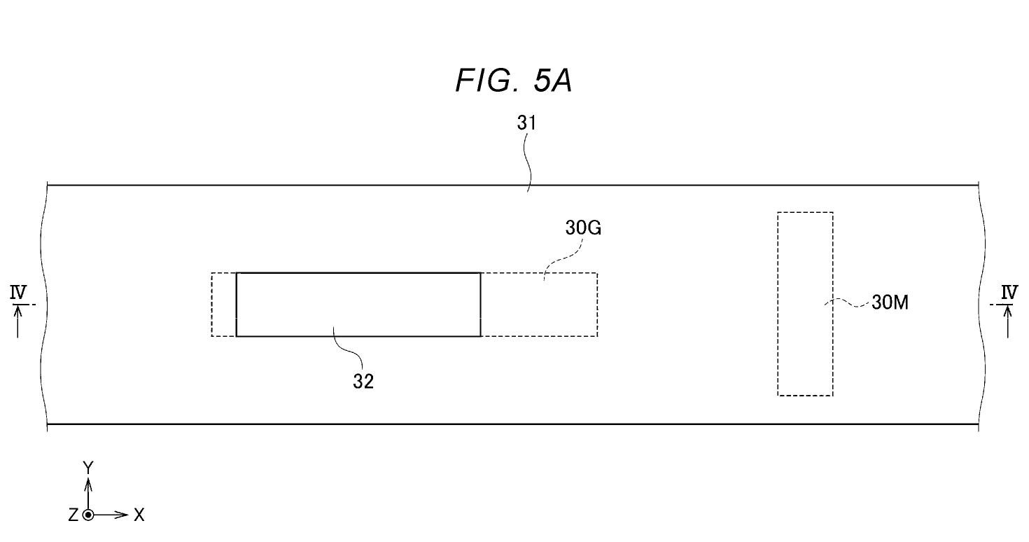

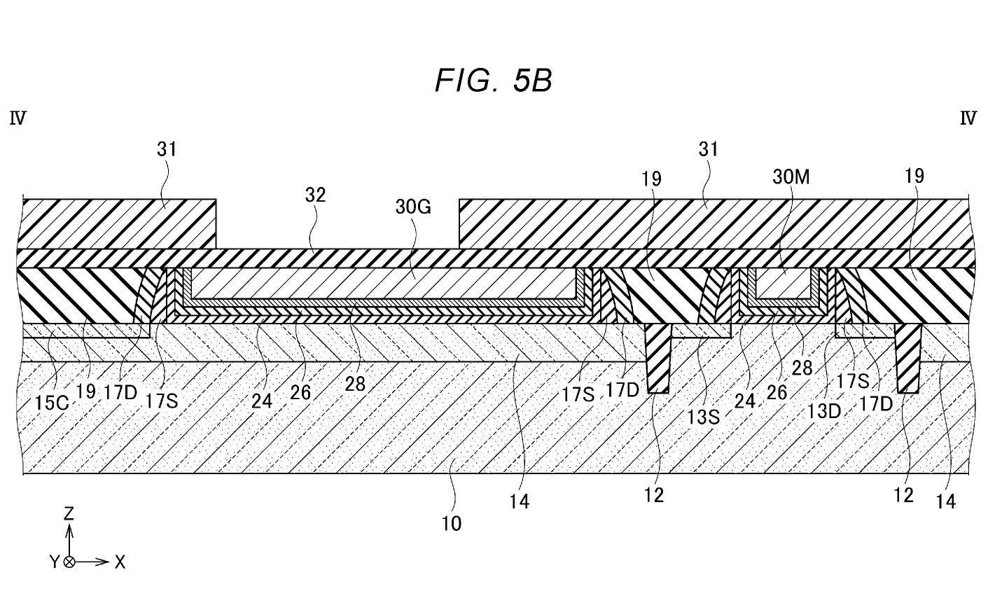

(B) FIG. 5A is a plan view of a method of manufacturing the semiconductor device according to the first embodiment, and FIG. 5B is a cross-sectional view taken along line IV-IV in FIG. 5A. Next, as shown in FIGS. 5A and 5B, a window of a capacitance element portion is opened by a lithography step after a resist layer 31 is applied to the entire surface.

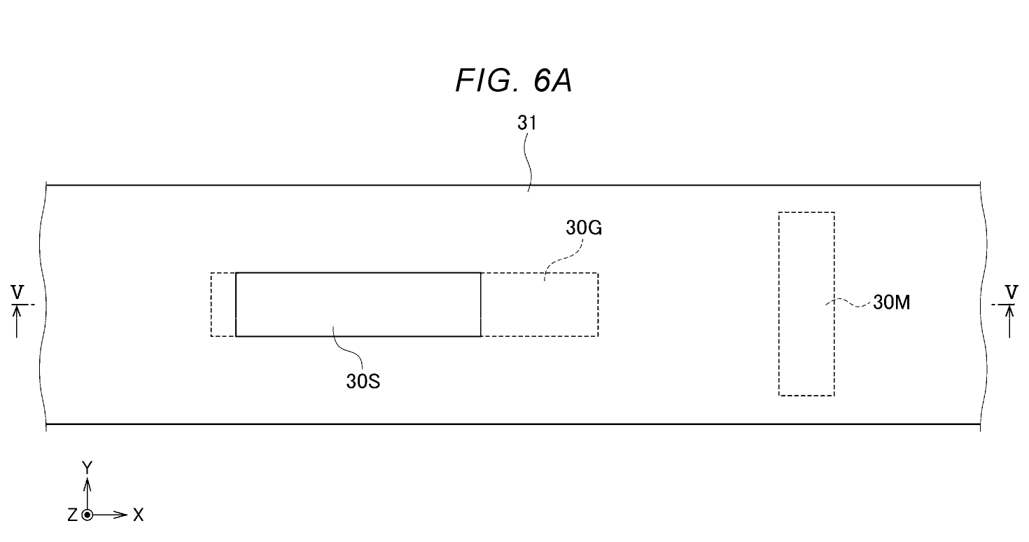

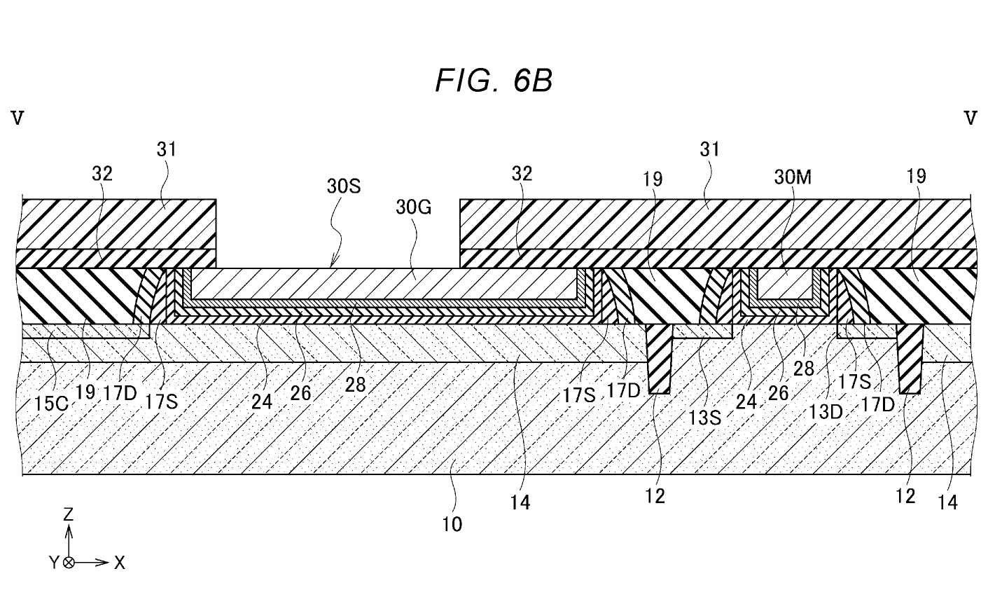

(C) FIG. 6A is a plan view of a method of manufacturing the semiconductor device according to the first embodiment, and FIG. 6B is a cross-sectional view taken along line V-V in FIG. 6A. Next, as shown in FIGS. 6A and 6B, the insulating film 32 of the capacitance element portion is removed. Here, in a removal step of the insulating film 32, the removal is performed by an etching technique such as wet etching or reactive ion etching (RIE).

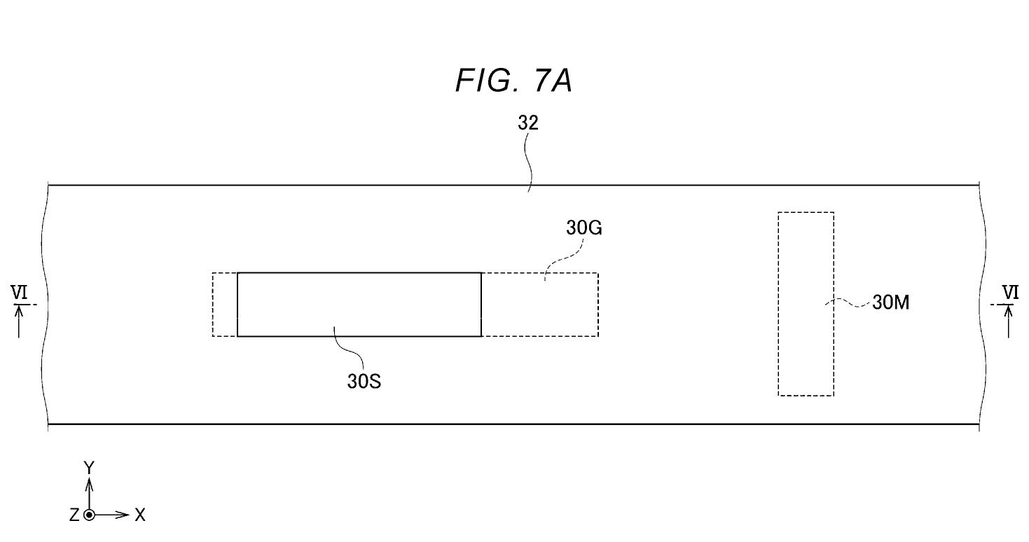

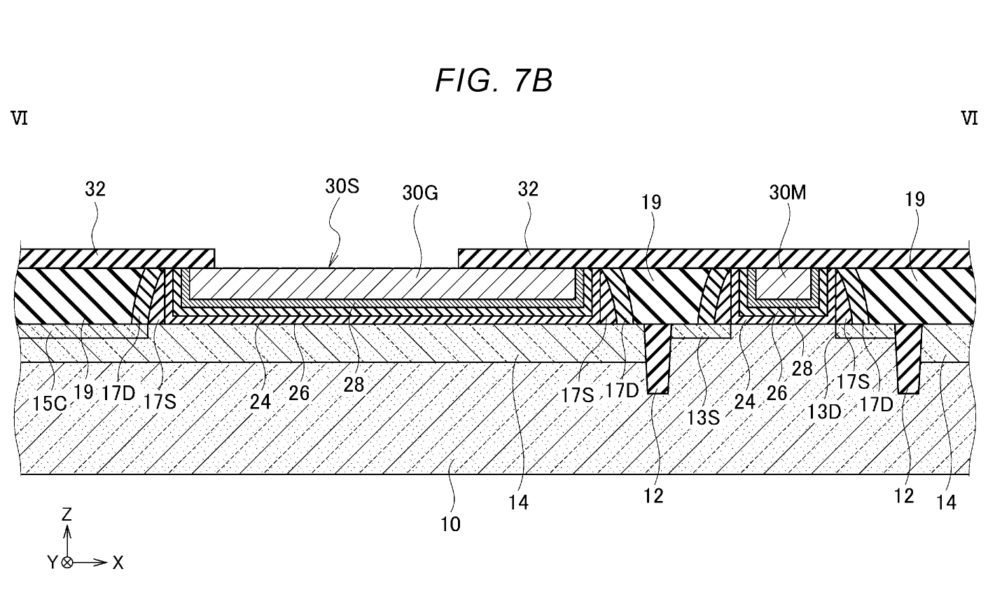

(D) FIG. 7A is a plan view of a method of manufacturing the semiconductor device according to the first embodiment, and FIG. 7B is a cross-sectional view taken along line VI-VI in FIG. 7A. Next, as shown in FIGS. 7A and 7B, the resist layer 31 is removed to expose the surface 30S of the electrode layer 30G.

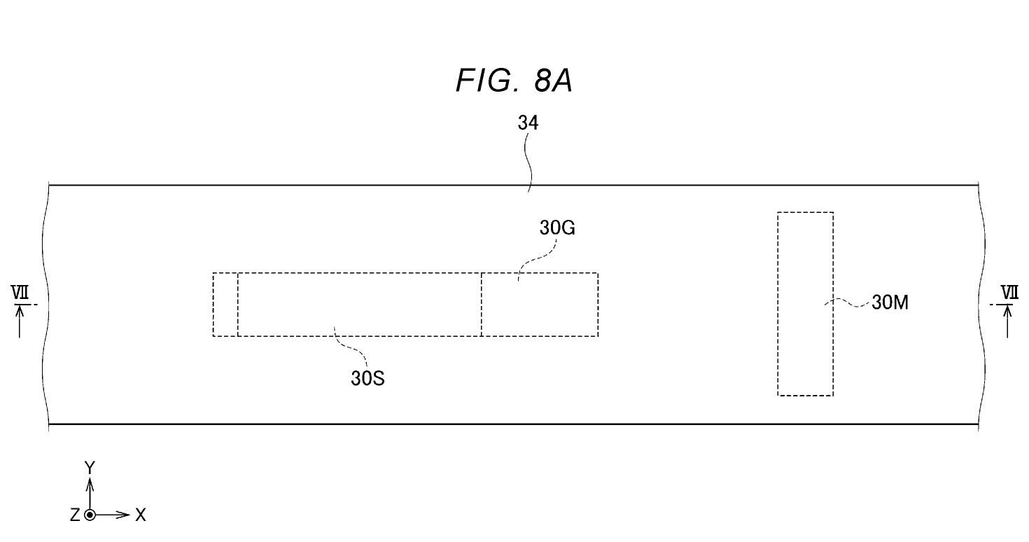

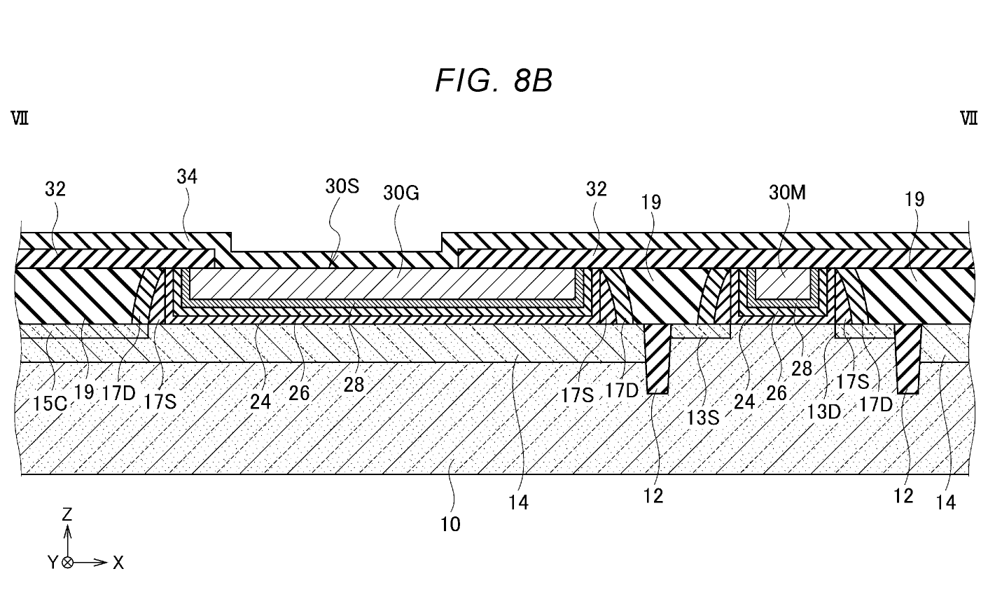

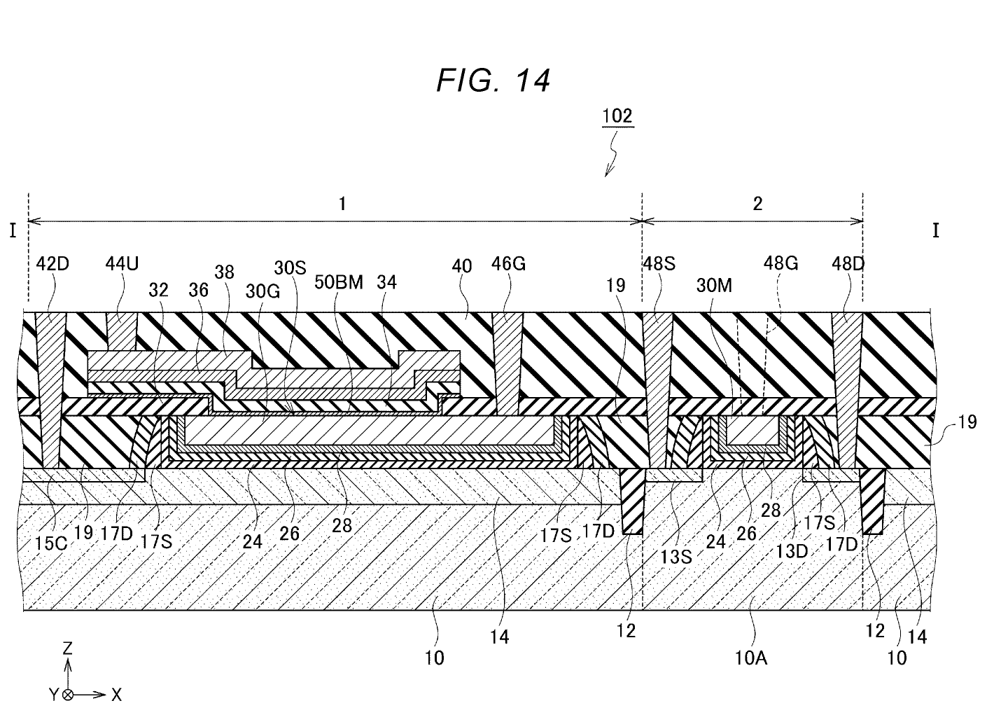

(E) FIG. 8A is a plan view of a method of manufacturing the semiconductor device according to the first embodiment, and FIG. 8B is a cross-sectional view taken along line VII-VII in FIG. 8A. Next, as shown in FIGS. 8A and 8B, the insulating film 34 of the capacitance element 1 is formed on the entire surface of the device. In order to reduce the influence on the element characteristics caused by the surface roughness of the exposed region of the lower electrode layer 30G of the capacitance element 1, the metal layer 50BM (refer to FIG. 14) may be formed as a barrier metal before the insulating film 34 is formed.

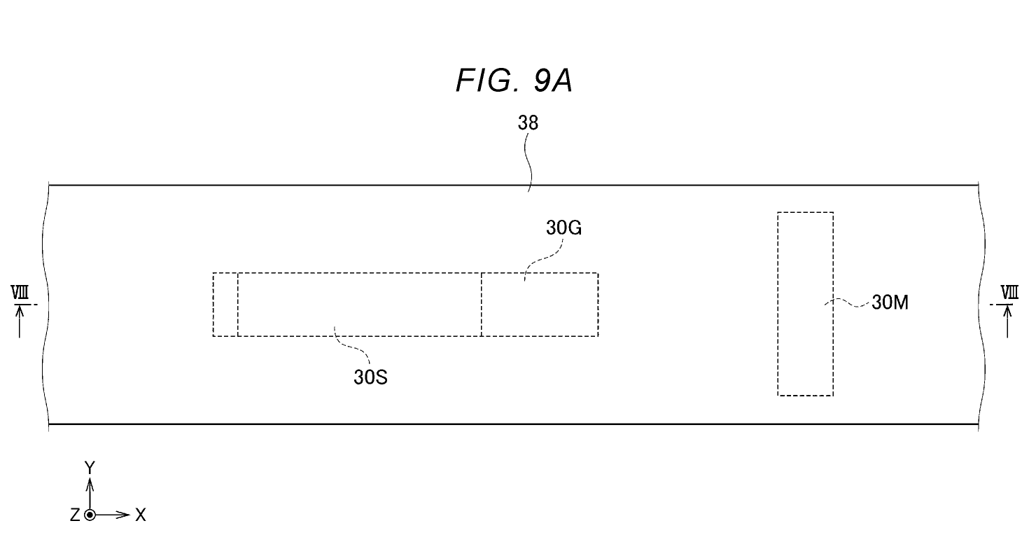

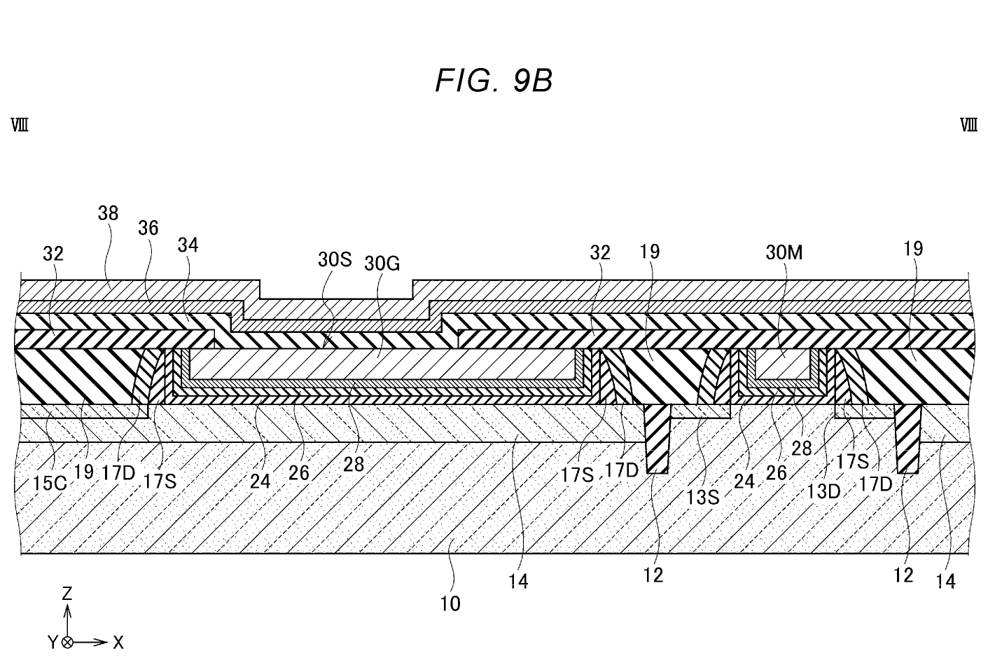

(F) FIG. 9A is a plan view of a method of manufacturing the semiconductor device according to the first embodiment, and FIG. 9B is a cross-sectional view taken along line VIII-VIII in FIG. 9A. Next, as shown in FIGS. 9A and 9B, the upper electrode layer 38 of the capacitance element 1 is formed on the entire surface of the device. As shown in FIG. 9B, in order to reduce the influence on the element characteristics caused by the surface roughness of the exposed region of the insulating film 34 of the capacitance element 1, the metal layer 36 may be formed as a barrier metal after the insulating film 34 is formed and before the upper electrode layer 38 is formed.

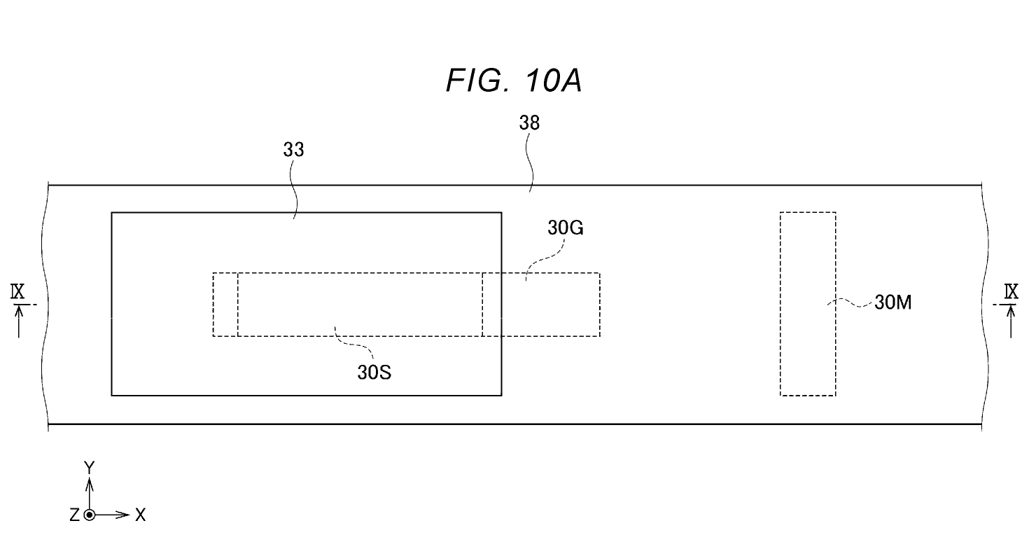

(G) FIG. 10A is a plan view of a method of manufacturing the semiconductor device according to the first embodiment, and FIG. 10B is a cross-sectional view taken along line IX-IX in FIG. 10A. Next, as shown in FIGS. 10A and 10B, the resist layer 33 for removing the upper electrode layer 38 of the capacitance element 1 by lithography is formed on the entire surface of the device and patterned.

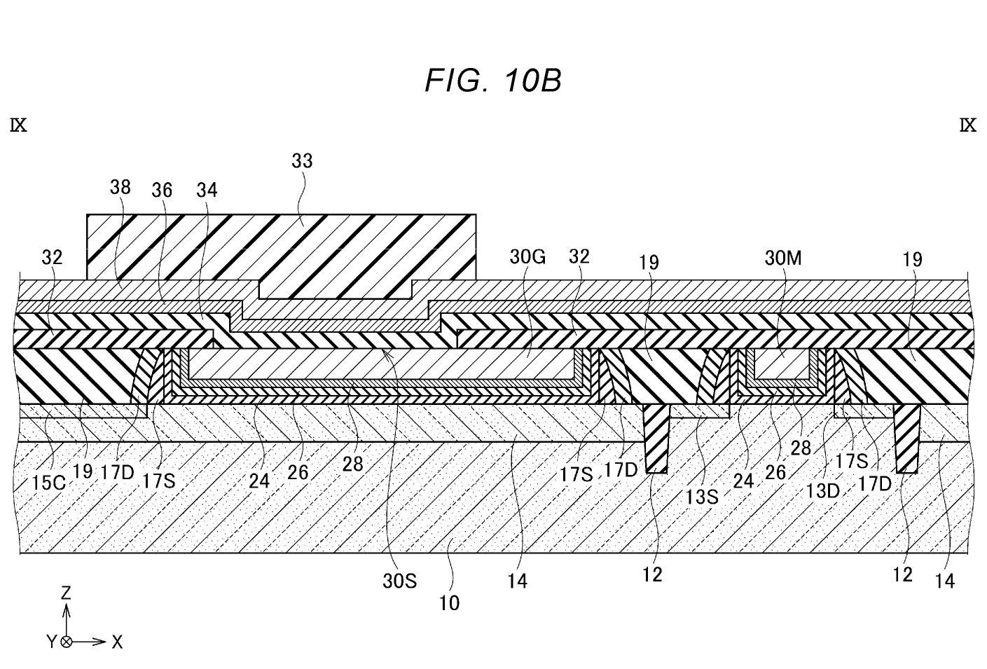

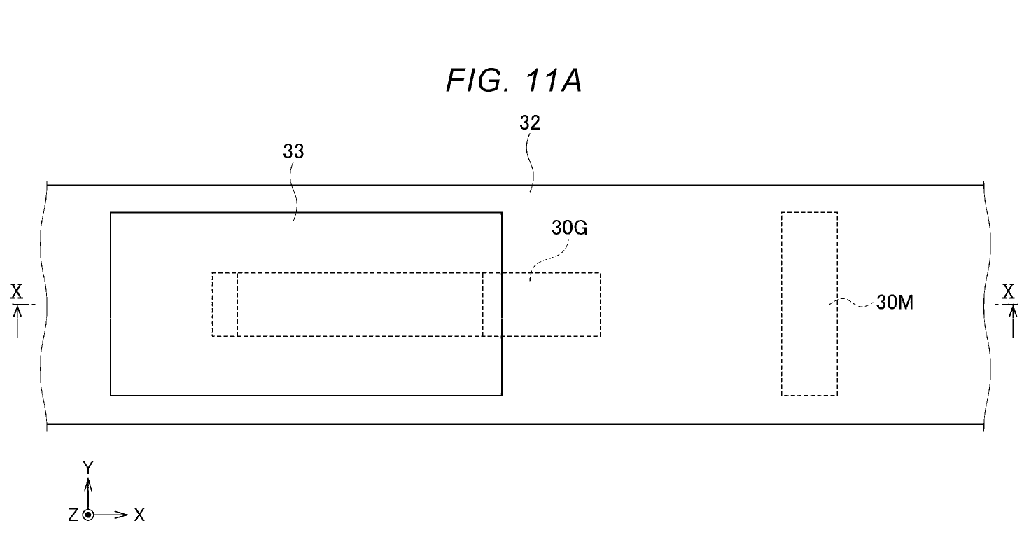

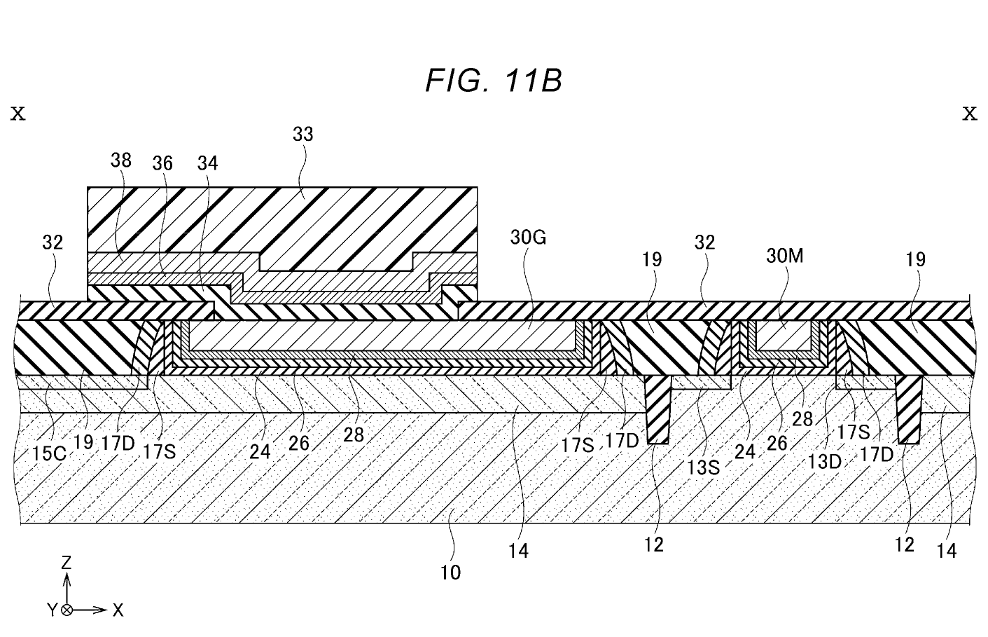

(H) FIG. 11A is a plan view of a method of manufacturing the semiconductor device according to the first embodiment, and FIG. 11B is a cross-sectional view taken along line X-X in FIG. 11A. Next, as shown in FIGS. 11A and 11B, the upper electrode layer 38, the metal layer 36, and the insulating film 34 are removed by an etching technique such as RIE using the resist layer 33 as a mask. Here, an etching step is executed until the surface of the insulating film 32, which is called a block film, is exposed, and stopped.

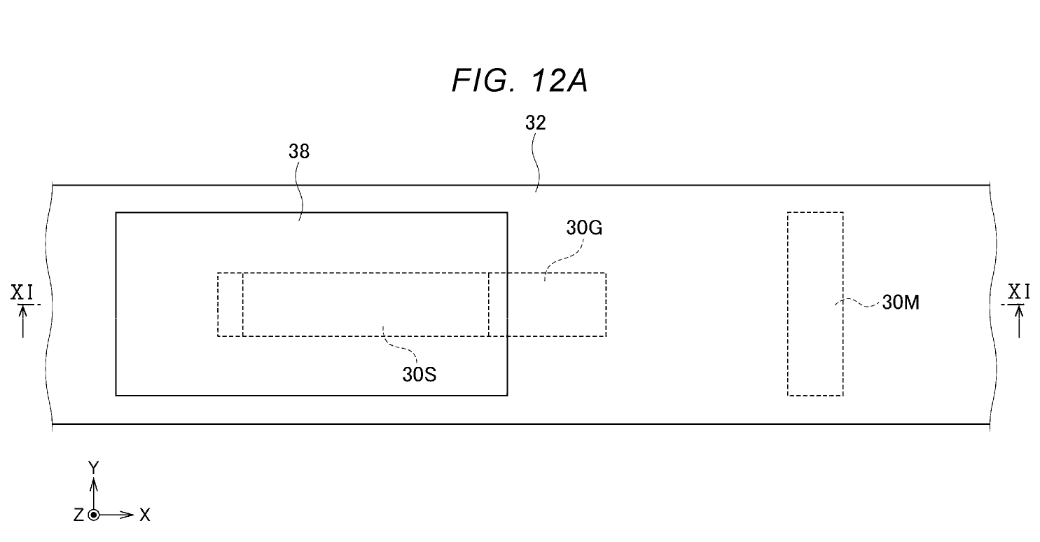

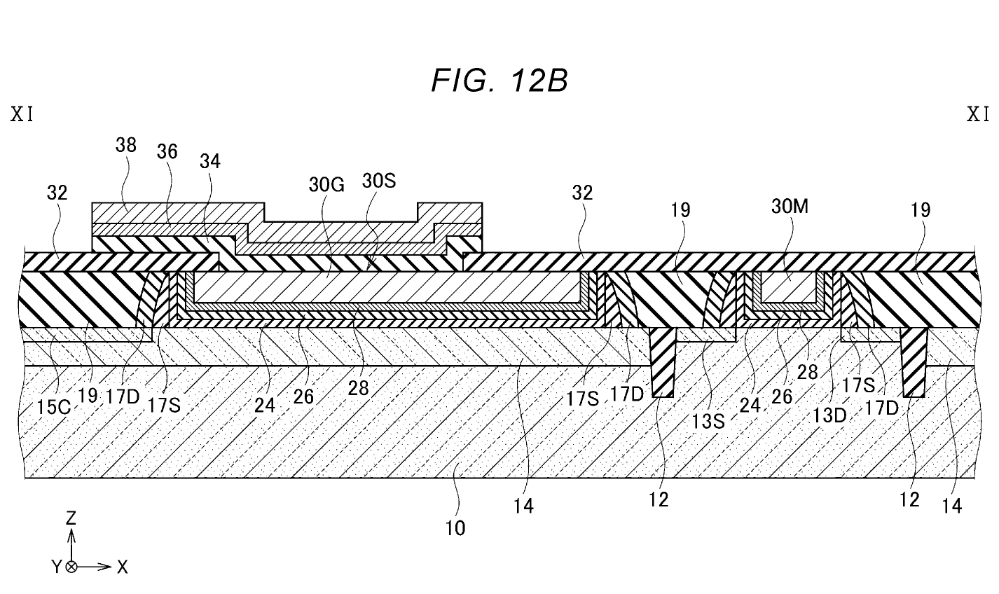

(I) FIG. 12A is a plan view of a method of manufacturing the semiconductor device according to the first embodiment, and FIG. 12B is a cross-sectional view taken along line XI-XI in FIG. 12A. Next, as shown in FIGS. 12A and 12B, the resist layer 33 is removed by the etching technique to expose the surface of the upper electrode layer 38.

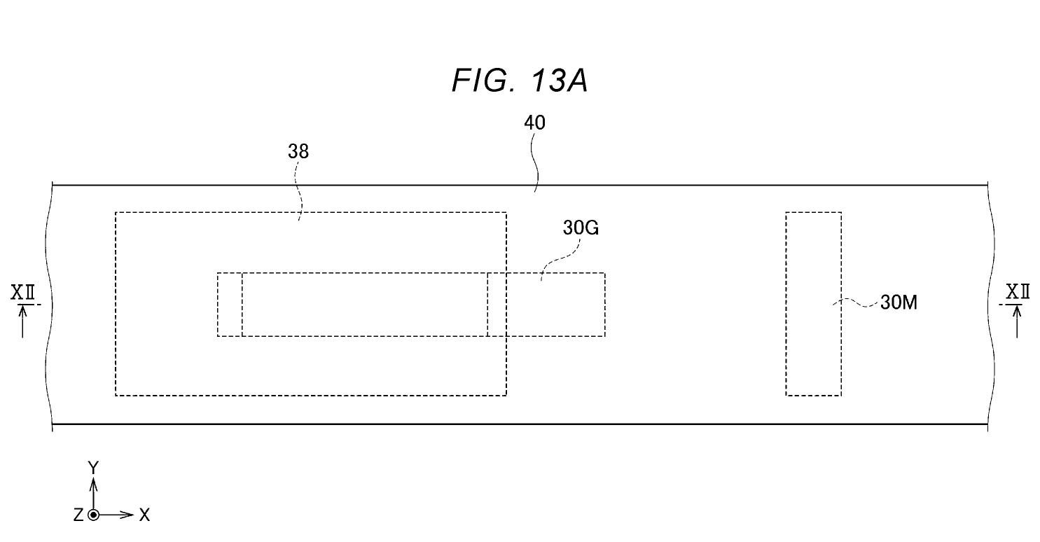

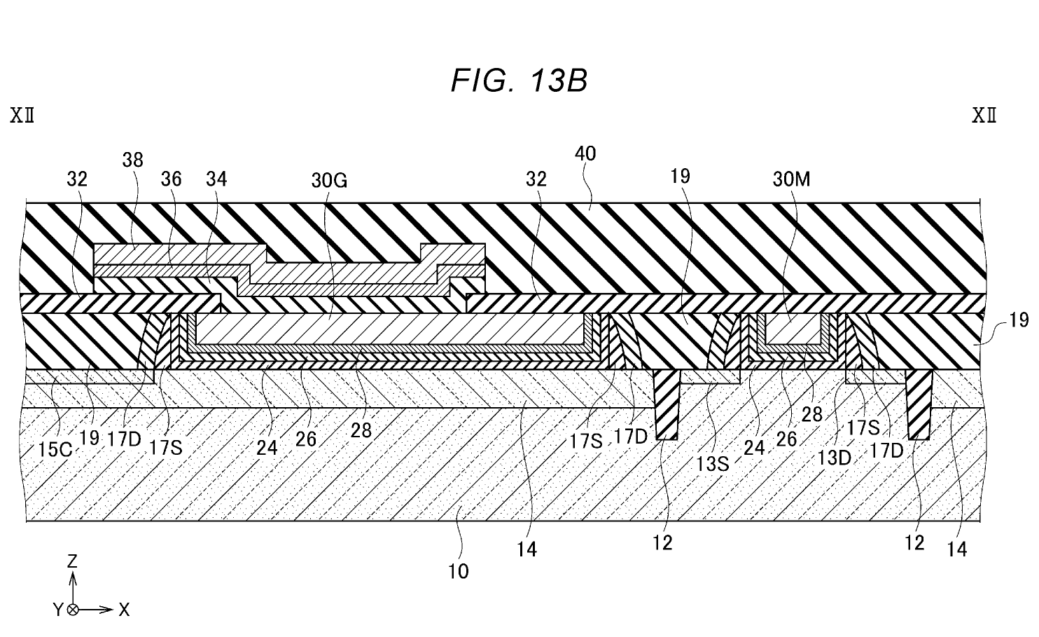

(J) FIG. 13A is a plan view of a method of manufacturing the semiconductor device according to the first embodiment, and FIG. 13B is a cross-sectional view taken along line XII-XII in FIG. 13A. Next, as shown in FIGS. 13A and 13B, an interlayer insulating film 40 is formed on the entire surface of the device.

(K) Next, as shown in FIGS. 1A and 1B, a window is opened in the interlayer insulating film 40 by the lithography step, and the contact 42D connected to the diffusion layer 15C, the contact 44U connected to the upper electrode layer 38, the contact 46G connected to the lower electrode layer 30G, a contact 48S connected to the diffusion layer 13S, a contact 48G connected to the electrode layer 30M, and a contact 48D connected to the diffusion layer 13D are formed.

### Effects of First Embodiment

According to the first embodiment, the restriction of the vertical structure specific to the RMG process is eliminated, the process difficulty is reduced, and the freedom of setting the film thickness of the insulating film and the film thickness of the upper electrode can be ensured.

### Second Embodiment

FIG. 14 is a cross-sectional view of a semiconductor device 102 according to the second embodiment. The plan view of the semiconductor device 102 according to the second embodiment is the same as in FIG. 1A. FIG. 14 corresponds to the cross-sectional structure taken along line I-I in FIG. 1A, as in FIG. 1B. As shown in FIG. 14, the semiconductor device 102 according to the second embodiment includes a metal layer 50BM between the insulating film 34 and the lower electrode layer 30G. The metal layer 50BM is called a barrier metal (BM). The metal layer 50BM includes, for example, a single layer or a multilayer selected from the group consisting of titanium (Ti), titanium nitride (TiN), tantalum nitride (TaN), tantalum (Ta), or tungsten (W).

In the semiconductor device 102 according to the second embodiment, by providing the metal layer 50BM under the insulating film 34 and electrically connecting the metal layer 50BM to the lower electrode layer 30G, the capacitor area can be substantially expanded by using the metal layer 50BM as the lower electrode layer, regardless of the area of the lower electrode layer 30G. That is, the metal layer 50BM not only has the effect as the barrier metal (BM) but also functions as a substantial area expansion layer of the lower electrode layer, and the capacitance value of the capacitor CU can be randomly increased together with the facing upper electrode layer 38. Other configurations are the same as those in the first embodiment.

### Method of Manufacturing Semiconductor Device according to Second Embodiment

In the method of manufacturing a semiconductor device according to the second embodiment, after a step shown in FIGS. 7A and 7B, the metal layer 50BM is formed on the entire surface of the device. Thereafter, the insulating film 34 is formed on the entire surface of the device. Other manufacturing steps are the same as those in the first embodiment. In this manner, the metal layer 50BM may be interposed between the insulating film 34 and the lower electrode layer 30G before the insulating film 34 is formed.

### Effects of Second Embodiment

According to the second embodiment, the restriction of the vertical structure specific to the RMG process is eliminated, the process difficulty is reduced, and the freedom of setting the film thickness of the insulating film and the film thickness of the upper electrode can be ensured.

### Third Embodiment

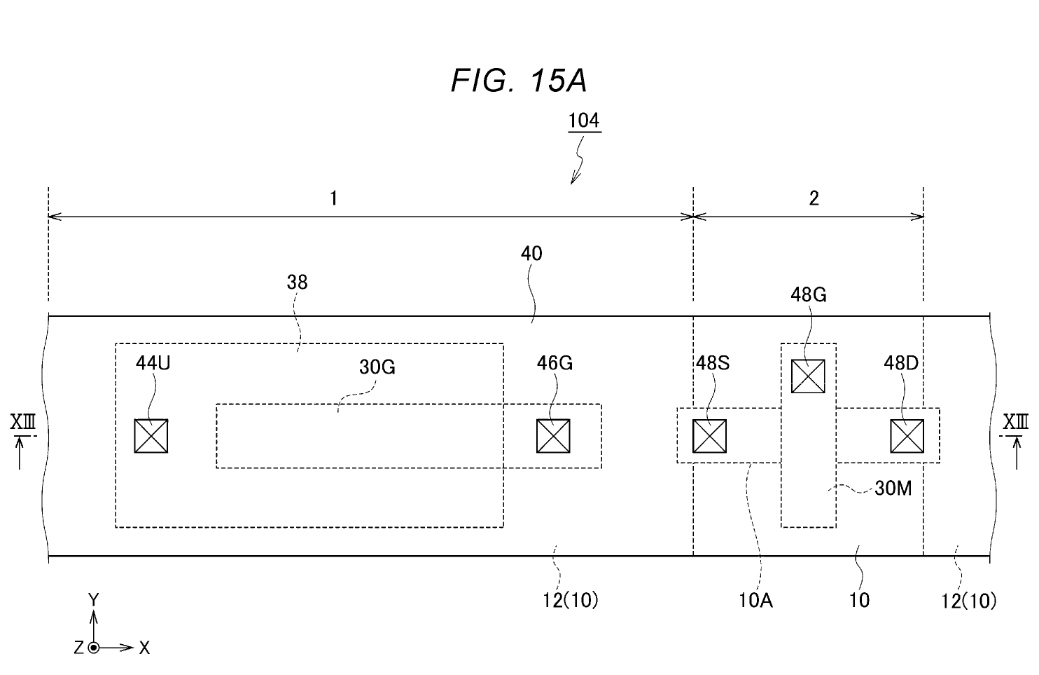

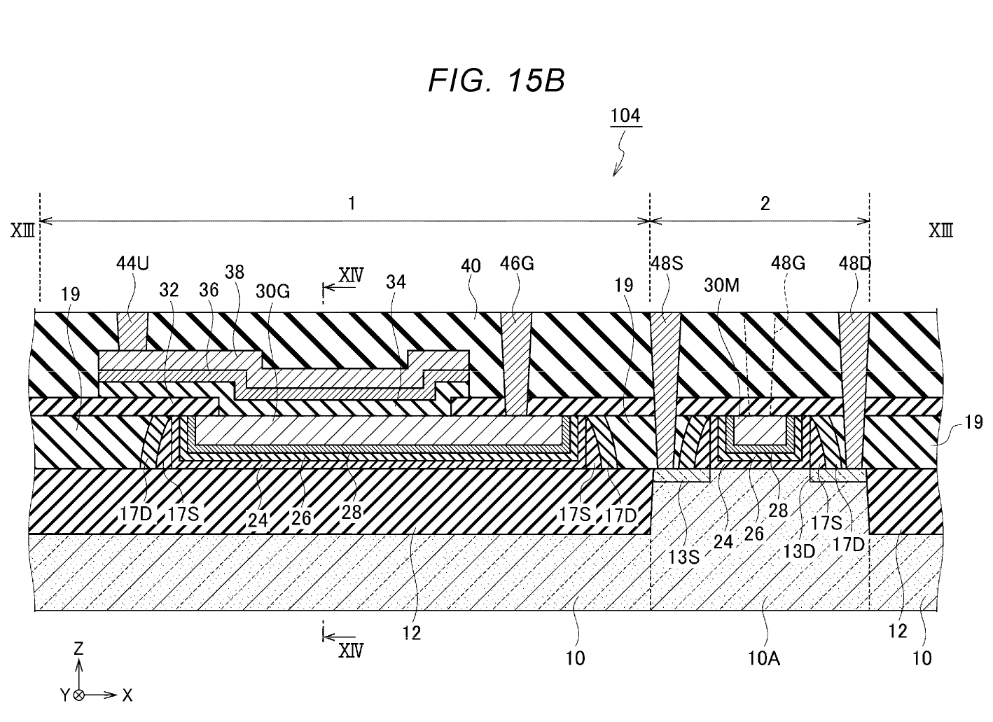

FIG. 15A is a plan view of a semiconductor device 104 according to the third embodiment. FIG. 15B is a cross-sectional view taken along line XIII-XIII in FIG. 15A.

As shown in FIGS. 15A and 15B, the capacitance element 1 of the semiconductor device 104 according to the third embodiment includes the semiconductor substrate 10, the separation region 12 provided on the semiconductor substrate 10, the lower electrode layer 30G provided on the separation region 12 and replacing a dummy polysilicon layer, the insulating film 34 for a thick film capacitance element provided on the upper portion of the lower electrode layer 30G, and the upper electrode layer 38 provided on the upper portion of the insulating film 34.

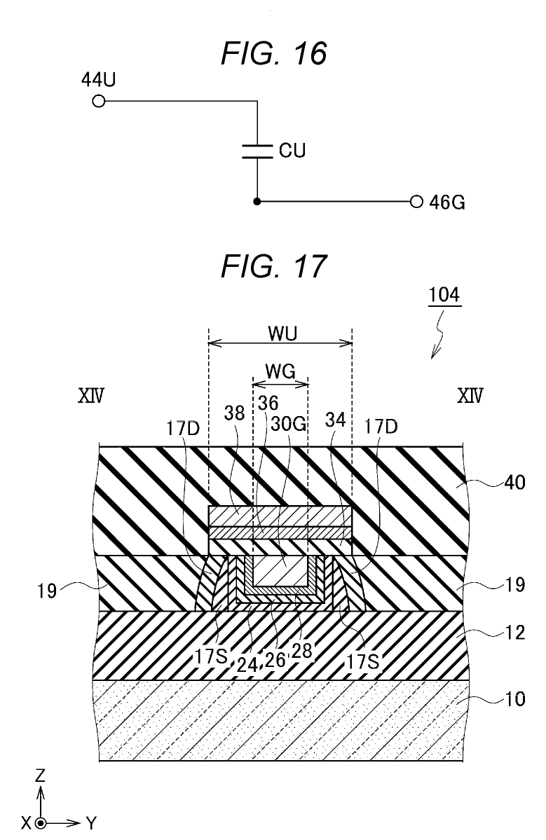

FIG. 16 is a circuit diagram of the semiconductor device 104 according to the third embodiment.

As shown in FIG. 16, the capacitance element 1 can be regarded as a capacitor CU formed by the upper electrode layer 38, the insulating film 34, and the lower electrode layer 30G. The capacitor CU is connected between the contact 44U connected to the upper electrode layer 38 and the contact 46G connected to the lower electrode layer 30G. Since the separation region 12 is formed instead of the diffusion layer 14, the capacitor CB is not formed.

FIG. 17 is a cross-sectional view taken along line XIV-XIV in FIG. 15B.

The film thickness of the insulating film 34 of the capacitance element 1 is relatively thick in order to form the capacitance element 1 having a high breakdown voltage. As shown in FIG. 17, the width WU of the upper electrode layer 38 in the Y direction is wider than the width WG of the lower electrode layer 30G in the Y direction. As shown in FIGS. 15B and 17, the capacitance element 1 of the semiconductor device 104 according to the third embodiment is not restricted by the vertical structure specific to the RMG process.

In the semiconductor device 104 according to the third embodiment, the metal layer 50BM may be provided between the insulating film 34 and the lower electrode layer 30G. Other configurations are the same as those in the first embodiment.

### Method of Manufacturing Semiconductor Device according to Third Embodiment

A method of manufacturing a semiconductor device according to the third embodiment is the same as the method of manufacturing a semiconductor device according to the first embodiment because the diffusion layer 14 only replaces the separation region 12.

### Effects of Third Embodiment

According to the third embodiment, the restriction of the vertical structure specific to the RMG process is eliminated, the process difficulty is reduced, and the freedom of setting the film thickness of the insulating film and the film thickness of the upper electrode can be ensured.

### Fourth Embodiment

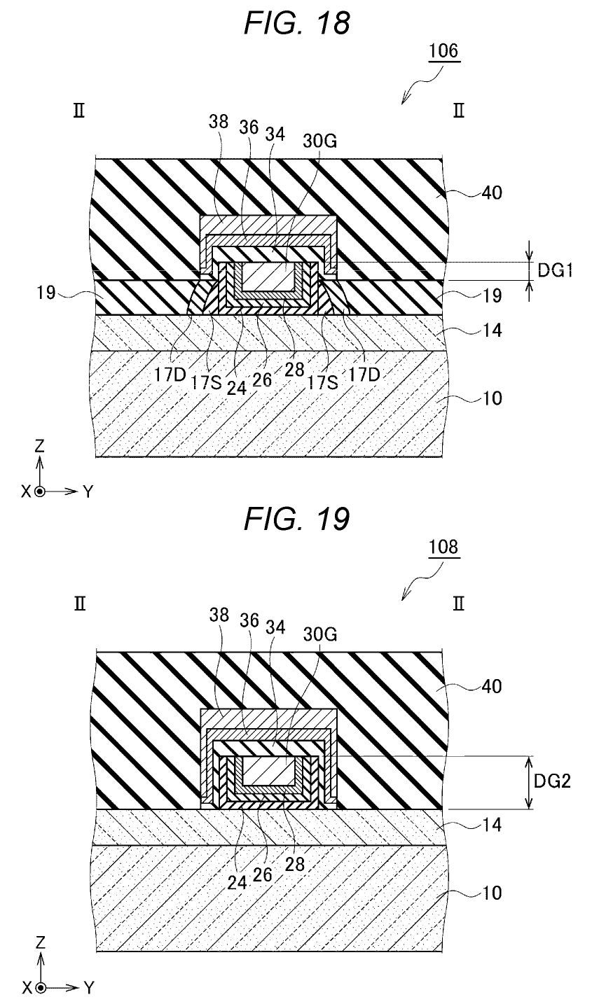

FIG. 18 is a cross-sectional view of a semiconductor device 106 according to the fourth embodiment. FIG. 18 corresponds to the cross-sectional structure taken along line II-II in FIG. 1B.

The semiconductor device 106 according to the fourth embodiment is an example in which the exposed surface of the lower electrode layer 30G of the capacitance element 1 is exposed not only on the upper surface but also on the side surface of the gate.

The lower electrode layer 30G of the capacitance element 1 faces the upper electrode layer 38 in the Z direction via the insulating film 34. Furthermore, the lower electrode layer 30G of the capacitance element 1 faces the high-k dielectric layer 24 in the plus and minus Y directions via the insulating film 34. That is, the upper electrode layer 38 has a structure in which the upper electrode layer 38 faces not only the upper surface of the lower electrode layer 30G but also the side surface of the lower electrode layer 30G via the insulating film 34. Other configurations are the same as those in the first embodiment.

In the semiconductor device 106 according to the fourth embodiment, the surface of the interlayer insulating film 19 is retracted by DG1 in the minus Z direction to expand the contact area between the lower electrode layer 30G and the upper electrode layer 38 facing each other. As a result, the contact area between the lower electrode layer 30G and the upper electrode layer 38 can be expanded, and the element capacitance can be improved.

In the semiconductor device 106 according to the fourth embodiment, the capacitance value of the capacitor CU can be increased as compared with the semiconductor device 100 according to the first embodiment. In the semiconductor device 106 according to the fourth embodiment, the diffusion layer 14 is provided, so that the capacitor CB is provided, and the capacitance value is the same as that of the semiconductor device 100 according to the first embodiment.

In the semiconductor device 106 according to the fourth embodiment, the side surface of the gate structure that functions as the lower electrode layer 30G of the capacitance element is exposed, and the insulating film 34 and the upper electrode layer 38 are rounded around the side surface, so that the effective area of the capacitance value can be increased. As a result, it is possible to reduce the layout by improving the areal capacitance ratio with respect to the layout area of the capacitance element 1.

### Effect of Improving Capacitance

A simulation was performed on the effect of improving the capacitance value formed in the upper electrode layer 38. In the simulation, the width WG of the lower electrode layer 30G in the Y direction was set to a maximum of approximately 1000 nm, and the thickness in the Z direction was set to approximately 30 nm. The width WG in the Y direction is the same as in FIG. 17. In the semiconductor device 106 according to the fourth embodiment, when the side surfaces in the plus and minus Y directions are rounded by approximately 10 nm, DG1 = 10 nm, 20 nm/1000 nm, and the width in the Y direction is improved by approximately 2% with respect to the maximum width 1000 nm in the Y direction, as compared with the case where there is no rounding (refer to FIGS. 3 and 17). When the plus and minus direction is rounded by 20 nm, DG1 = 20 nm, 40 nm/1000 nm, and the width in the Y direction is improved by approximately 4% with respect to the maximum width of 1000 nm in the Y direction.

### Method of Manufacturing Semiconductor Device according to Fourth Embodiment

A method of manufacturing a semiconductor device according to the fourth embodiment has a step of retracting the interlayer insulating film 19 by DG1 in the minus Z direction by RIE after the manufacturing step shown in FIGS. 4A and 4B. Subsequent steps are substantially the same as the method of manufacturing a semiconductor device according to the first embodiment.

### Effects of Fourth Embodiment

According to the fourth embodiment, the restriction of the vertical structure specific to the RMG process is eliminated, the process difficulty is reduced, and the freedom of setting the film thickness of the insulating film and the film thickness of the upper electrode can be ensured. In addition, according to the fourth embodiment, since there is no restriction on the gate width specific to the RMG process, the capacitance area ratio can be improved with respect to the layout area, and the capacitance element layout can be reduced.

### Fifth Embodiment

FIG. 19 is a cross-sectional view of a semiconductor device 108 according to the fifth embodiment. FIG. 19 corresponds to the cross-sectional structure taken along line II-II in FIG. 1B. The semiconductor device 106 according to the fifth embodiment is also an example in which the exposed surface of the lower electrode layer 30G of the capacitance element 1 is exposed on not only the upper surface but also on the side surface of the gate. The lower electrode layer 30G of the capacitance element 1 faces the upper electrode layer 38 in the Z direction via the insulating film 34. Furthermore, the lower electrode layer 30G of the capacitance element 1 faces the upper electrode layer 38 in the plus and minus Y directions via the high-k dielectric layer 24 and the insulating film 34.

In the semiconductor device 108 according to the fifth embodiment, the surface of the interlayer insulating film 19 is retracted by DG2 in the minus Z direction to expand the contact area between the lower electrode layer 30G and the upper electrode layer 38 facing each other. That is, the interlayer insulating film 19 is substantially retracted to the diffusion layer 14. As a result, the contact area between the lower electrode layer 30G and the upper electrode layer 38 can be expanded, and the element capacitance can be improved.

In the semiconductor device 108 according to the fifth embodiment, the capacitance value of the capacitor CU can be further increased as compared with the semiconductor device 106 according to the fourth embodiment. In the semiconductor device 108 according to the fifth embodiment, the diffusion layer 14 is provided, so that the capacitor CB is provided, and the capacitance value is the same as that of the semiconductor device 100 according to the first embodiment. In the semiconductor device 108 according to the fifth embodiment, the capacitance element having a gate-all-around structure is formed around the upper surface, the side surface, and the bottom surface of the lower electrode layer 30G by a combination structure of the capacitor CU and the capacitor CB.

### Effect of Improving Capacitance

A simulation was performed on the effect of improving the capacitance value formed in the upper electrode layer 38. In the simulation, the width WG of the lower electrode layer 30G in the Y direction was set to a maximum of approximately 1000 nm, and the thickness in the Z direction was set to approximately 30 nm. In the semiconductor device 108 according to the fifth embodiment, the rounding is 30 nm around the entire periphery of the gate electrode layer, as compared with the case where there is no rounding (refer to FIGS. 3 and 17). Considering the thickness of the lower electrode layer 30G in the Z direction of approximately 30 nm (substantially equal to DG2), and the width of the bottom surface of the lower electrode layer 30G in the Y direction of approximately 10 nm, the width in the Y direction is 70 nm/1000 nm with respect to the maximum width of 1000 nm in the Y direction, and is improved by approximately 7%.

### Method of Manufacturing Semiconductor Device according to Fifth Embodiment

A method of manufacturing a semiconductor device according to the fifth embodiment has a step of retracting the interlayer insulating film 19 by DG2 in the minus Z direction by RIE and exposing the surface of the diffusion layer 14 after the manufacturing steps shown in FIGS. 4A and 4B. Subsequent steps are substantially the same as the method of manufacturing a semiconductor device according to the first embodiment.

### Effects of Fifth Embodiment

According to the fifth embodiment, the restriction of the vertical structure specific to the RMG process is eliminated, the process difficulty is reduced, and the freedom of setting the film thickness of the insulating film and the film thickness of the upper electrode can be ensured. In addition, according to the fifth embodiment, since there is no restriction on the gate width specific to the RMG process, the capacitance area ratio can be improved with respect to the layout area, and the capacitance element layout can be reduced.

### Sixth Embodiment

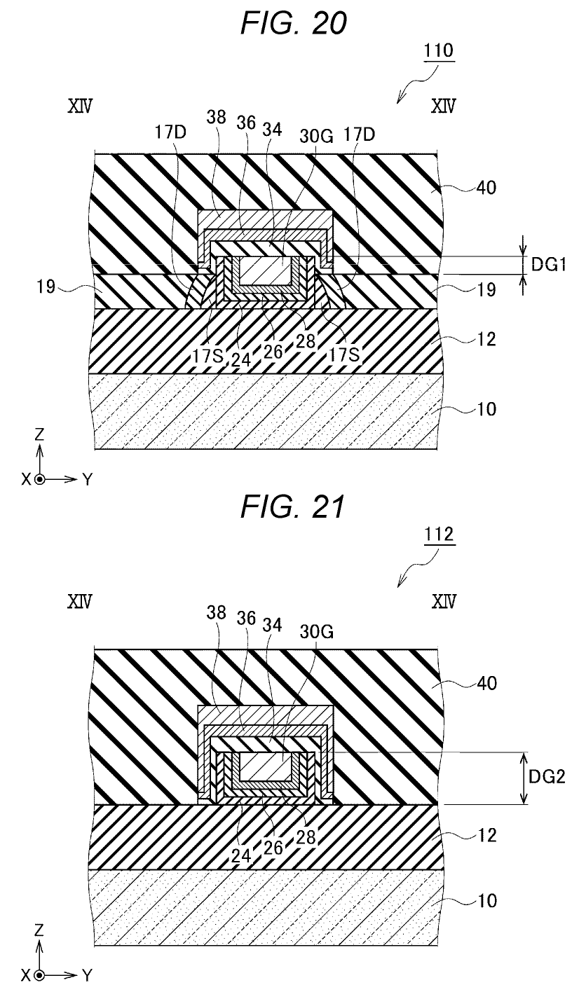

FIG. 20 is a cross-sectional view of a semiconductor device 110 according to the sixth embodiment. FIG. 20 corresponds to the cross-sectional structure taken along line XIV-XIV in FIG. 15B. The semiconductor device 110 according to the sixth embodiment is an example in which the capacitance element 1 is formed on the separation region 12, as in the semiconductor device 104 according to the third embodiment.

In the semiconductor device 110 according to the sixth embodiment, the surface of the interlayer insulating film 19 is retracted by DG1 in the minus Z direction in order to expand the contact area between the lower electrode layer 30G and the upper electrode layer 38 facing each other, as in the semiconductor device 106 (FIG. 18) according to the fourth embodiment. As a result, the contact area between the lower electrode layer 30G and the upper electrode layer 38 can be expanded, and the element capacitance can be improved.

In the semiconductor device 110 according to the sixth embodiment, the capacitance value of the capacitor CU can be increased as compared with the semiconductor device 104 according to the third embodiment. Other configurations are the same as those of the semiconductor device 106 according to the fourth embodiment.

### Method of Manufacturing Semiconductor Device according to Sixth Embodiment

A method of manufacturing a semiconductor device according to the sixth embodiment has a step of retracting the interlayer insulating film 19 by DG1 in the minus Z direction by RIE. Subsequent steps are substantially the same as the method of manufacturing a semiconductor device according to the first embodiment.

### Effects of Sixth Embodiment

According to the sixth embodiment, the restriction of the vertical structure specific to the RMG process is eliminated, the process difficulty is reduced, and the freedom of setting the film thickness of the insulating film and the film thickness of the upper electrode can be ensured. In addition, according to the sixth embodiment, since there is no restriction on the gate width specific to the RMG process, the capacitance area ratio can be improved with respect to the layout area, and the capacitance element layout can be reduced.

### Seventh Embodiment

FIG. 21 is a cross-sectional view of a semiconductor device 112 according to the seventh embodiment. FIG. 21 corresponds to the cross-sectional structure taken along line XIV-XIV in FIG. 15B. The semiconductor device 112 according to the seventh embodiment is an example in which the capacitance element 1 is formed on the separation region 12, as in the semiconductor device 104 according to the third embodiment.

In the semiconductor device 112 according to the seventh embodiment, the surface of the interlayer insulating film 19 is retracted by DG2 in the minus Z direction in order to expand the contact area between the lower electrode layer 30G and the upper electrode layer 38 facing each other, as in the semiconductor device 108 (FIG. 19) according to the fifth embodiment. That is, the interlayer insulating film 19 is substantially retracted to the diffusion layer 14. As a result, the contact area between the lower electrode layer 30G and the upper electrode layer 38 can be expanded, and the element capacitance can be improved.

In the semiconductor device 112 according to the seventh embodiment, the capacitance value of the capacitor CU can be further increased as compared with the semiconductor device 110 according to the sixth embodiment. Other configurations are the same as those of the semiconductor device 108 according to the fifth embodiment.

### Method of Manufacturing Semiconductor Device according to Seventh Embodiment

A method of manufacturing a semiconductor device according to the seventh embodiment has a step of retracting the interlayer insulating film 19 by DG2 in the minus Z direction by RIE and exposing the surface of the diffusion layer 14. Subsequent steps are substantially the same as the method of manufacturing a semiconductor device according to the first embodiment.

### Effects of Seventh Embodiment

According to the seventh embodiment, the restriction of the vertical structure specific to the RMG process is eliminated, the process difficulty is reduced, and the freedom of setting the film thickness of the insulating film and the film thickness of the upper electrode can be ensured. In addition, according to the seventh embodiment, since there is no restriction on the gate width specific to the RMG process, the capacitance area ratio can be improved with respect to the layout area, and the capacitance element layout can be reduced.

### Combination Structure of Embodiment

As the semiconductor device according to the embodiment, the structures of the first to seventh embodiments may be combined as necessary to realize the capacitance element. In addition, as the semiconductor device according to the embodiment, a combination structure of a first structure in which the upper electrode layer 38 faces the upper surface of the lower electrode layer 30G via the insulating film 34, and a second structure in which the upper electrode layer 38 also faces the side surface of the lower electrode layer 30G via the insulating film 34 may be provided. Here, the first structure corresponds to the structure shown in FIG. 3 or 17. The second structure corresponds to the structure shown in FIGS. 18 to 21.

A thickness of a member constituting the semiconductor device, a distance between members, and the like in the present specification can be measured by using, for example, physical analysis using a secondary electron microscope (SEM) or a transmission electron microscope (TEM).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a capacitance element that includes a semiconductor substrate, a diffusion layer provided on the semiconductor substrate, and a first electrode layer provided on the diffusion layer; and
a transistor that includes an active region provided on the semiconductor substrate and electrically separated from the diffusion layer by a separation region, and a second electrode layer provided on the active region.

2. The semiconductor device according to claim 1, further comprising:
a first insulating film provided on the first electrode layer; and
a third electrode layer provided on the first insulating film.

3. The semiconductor device according to claim 2,
wherein
the first electrode layer and a gate insulating film are embedded in a groove having a gate shape, and
the second electrode layer and the gate insulating film are embedded in the groove having the gate shape.

4. The semiconductor device according to claim 3,
wherein the gate insulating film includes an oxide film and a high-k dielectric layer.

5. The semiconductor device according to claim 4, further comprising:
a metal-containing layer provided on the high-k dielectric layer;
a work function metal layer provided on the metal-containing layer; and
the first electrode layer and the second electrode layer provided on the work function metal layer.

6. The semiconductor device according to claim 5,
wherein the high-k dielectric layer includes a single layer or a multilayer selected from the group consisting of hafnium oxide (HfO₂), hafnium silicon oxide (HfSiO), lanthanum oxide (La₂O₃), tantalum oxide (Ta₂O₅), strontium titanate oxide (SrTiO₃), or zirconium oxide (ZrO₂).

7. The semiconductor device according to claim 5,
wherein the metal-containing layer includes a single layer or a multilayer selected from the group consisting of titanium nitride (TiN), tantalum nitride (TaN), tantalum (Ta), or tungsten (W).

8. The semiconductor device according to claim 5,
wherein the work function metal layer includes a single layer or a multilayer selected from the group consisting of aluminum (Al), lanthanum (La), titanium (Ti), titanium nitride (TiN), and tungsten (W).

9. The semiconductor device according to claim 5,
wherein the first electrode layer and the second electrode layer each include a single layer or a multilayer selected from the group consisting of tungsten (W), aluminum (Al), titanium (Ti), and titanium nitride (TiN).

10. The semiconductor device according to claim 3,
wherein the capacitance element includes a first capacitance element having the first electrode layer, the first insulating film, and the third electrode layer, and a second capacitance element having the first electrode layer, the gate insulating film, and the diffusion layer.

11. The semiconductor device according to claim 2, further comprising:
a first metal layer provided between the first insulating film and the third electrode layer.

12. The semiconductor device according to claim 11, further comprising:
a second metal layer provided between the first insulating film and the first electrode layer.

13. The semiconductor device according to claim 12,
wherein the first metal layer and the second metal layer each include a single layer or a multilayer selected from the group consisting of titanium (Ti), titanium nitride (TiN), tantalum nitride (TaN), tantalum (Ta), or tungsten (W).

14. A semiconductor device comprising:
a capacitance element that includes a semiconductor substrate, a separation region provided on the semiconductor substrate, and a first electrode layer provided on the separation region; and
a transistor that includes an active region provided on the semiconductor substrate and electrically separated by the separation region, and a third electrode layer provided on the active region.

15. The semiconductor device according to claim 14, further comprising:
a first insulating film provided on the first electrode layer; and
a third electrode layer provided on the first insulating film.

16. The semiconductor device according to claim 15,
wherein the third electrode layer faces an upper surface of the first electrode layer and a side surface of the first electrode layer via the first insulating film.

17. The semiconductor device according to claim 16, wherein
the third electrode layer faces an upper surface of the first electrode layer via the first insulating film, or
the third electrode layer faces a side surface of the first electrode layer via the first insulating film.

18. A method of manufacturing a semiconductor device that includes a capacitance element on a diffusion region or a separation region of a semiconductor substrate, and includes a transistor on an active region of the semiconductor substrate, the method comprising:
forming, in the capacitance element, a first dummy polysilicon layer on the diffusion region or the separation region, removing the first dummy polysilicon layer by etching, forming a first electrode layer by replacing the first dummy polysilicon layer on the diffusion region, forming a first insulating film on the first electrode layer, and forming a second electrode layer on the first insulating film; and
forming, in the transistor, a second dummy polysilicon layer simultaneously with forming the first dummy polysilicon layer on the active region, removing the second dummy polysilicon layer by etching, and forming a second electrode layer by replacing the second dummy polysilicon layer.

19. The method of manufacturing a semiconductor device according to claim 18,
wherein the first electrode layer is formed by peeling the first dummy polysilicon layer, and embedding a gate insulating film and the first electrode layer in a groove having a gate shape after peeling, and
the second electrode layer is formed by forming a source diffusion layer and a drain diffusion layer of the transistor using the second dummy polysilicon layer, and then peeling the second dummy polysilicon layer, and embedding the gate insulating film and the second electrode layer in the groove having the gate shape after peeling.

20. The method of manufacturing a semiconductor device according to claim 19,
wherein the gate insulating film is formed before the first electrode layer and the second electrode layer are formed.
